(19) United States
(12) Patent Application Publication
(10) Pub. No.: US 2024/0234283 A9
(43) Pub. Date: Jul. 11, 2024

(54) ELECTRONIC PACKAGE WITH INTEGRATED INTERCONNECT STRUCTURE

(71) Applicant: Intel Corporation, Santa Clara, CA (US)

(72) Inventors: Bok Eng CHEAH, Gelugor (MY); Seok Ling LIM, Kulim Kedah (MY); Jenny Shio Yin ONG, Bayan Lepas (MY); Jackson Chung Peng KONG, Tanjung Tokong (MY); Kooi Chi OOI, Gelugor (MY)

(21) Appl. No.: 17/968,830

(22) Filed: Oct. 19, 2022

(51) Int. Cl. H01L 23/498; H01L 21/48; H01L 23/64; H01L 25/00; H01L 25/065; H01L 25/16; H01L 25/18

(52) U.S. Cl. CPC H01L 23/49833; H01L 21/486; H01L 23/49827; H01L 23/642; H01L 25/0655; H01L 25/162; H01L 25/18; H01L 25/50; H01L 24/32

(57) ABSTRACT

A device is provided, including a package substrate including at least one opening extending through the package substrate, and an interconnect structure including a first segment and a second segment. The first segment may extend under a bottom surface of the package substrate and may further extend beyond a footprint of the package substrate. The second segment may extend vertically from the first segment and may extend at least partially through the at least one opening of the package substrate.

### BACKGROUND

In power delivery network (PDN), challenges of system power delivery are ascribed to device form-factor miniaturization, e.g., footprint or layer count reduction of an electronic package and/or a printed circuit board (PCB). Current PCB design implementation has some constraints, e.g., extensive power delivery network through multiple PCB and/or package transitions or discontinuities to achieve stringent direct current (DC) resistance and alternating current (AC) loop inductance for improved device performance.

Current solutions to address the above challenges include increasing package substrate layer count (e.g., one or more power (Vcc) and ground (Vss) reference planes) or package footprint to meet stringent DC resistance and/or voltage IR drop requirements. The package and/or platform footprint expansion may however inhibit device form-factor miniaturization. Other solutions may include increasing silicon Metal-Insulator-Metal Capacitors (MIMCap) and/or package decoupling capacitors for improved PDN impedance and power supply induced noise jitter (PSIJ) design specifications. This may lead to increased silicon manufacturing complexity and throughput time with the metal-in-metal capacitance.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1 shows a cross-sectional view of a device according to an aspect of the present disclosure.

FIG. 2A shows a cross-sectional view of a device according to another aspect of the present disclosure.

FIG. 2B shows a top view layout of the device according to the aspect as shown in FIG. 2A.

FIG. 2C shows a bottom view layout of the device according to the aspect as shown in FIG. 2A.

FIG. 3 shows a cross-sectional view of a device according to a further aspect of the present disclosure.

FIG. 4 shows a flow chart illustrating a method of forming a device according to an aspect of the present disclosure.

FIGS. 5A through 5H show cross-sectional views directed to an exemplary process flow for a method of making a device according to an aspect of the present disclosure.

FIG. 6 shows an illustration of a computing device that includes a semiconductor package according to a further aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure introduces an electronic package or assembly with integrated interconnect structure for improved computing performance and device miniaturization, for example, with integrated power/signal interconnect structure for improved power/signal integrity.

Advantages of the present disclosure may include improved electrical (power integrity) performance through streamlined and localized power delivery network (PDN) especially for 2.5D/3D stacked die packages. Improved alternating current (AC) loop inductance may be achieved through the tightly coupled power-ground (Vcc-Vss) network within the power delivery structure. Reduced direct current (DC) resistance may be also achieved through shorter power delivery interconnects and increased power plane thickness (e.g., >30 μm) and/or total area, without being restricted by conventional package manufacturing assembly process, i.e., homogenous metal layer thickness (approximately 15 μm) across the signal routing and the power delivery network.

Another advantage of the present disclosure may include device miniaturization through footprint reduction of the package and/or printed circuit board (PCB), e.g., reduced package and/or PCB layer count through a more direct and localized power delivery network, and Vss/Vcc ball grid array (BGA) count reduction.

Further advantages of the present disclosure may include improved signal integrity, i.e., less stringent PCB routing at solder ball breakout region through Vcc and/or Vss BGA count reduction to allow larger signal routing breakout real-estate for improved crosstalk noise coupling between adjacent signals. Additional Vss shielding from a second segment of the interconnect structure may improve current return paths especially for signals routed at PCB surface layer.

In all aspects, the present disclosure generally relates to a device that may include a package substrate including at least one opening extending through the package substrate, and an interconnect structure including a first segment and a second segment. The first segment may extend under a bottom surface of the package substrate and may further extend beyond a footprint of the package substrate. The second segment may extend vertically from the first segment and may extend at least partially through the at least one opening of the package substrate.

The present disclosure generally relates to a method of forming a device. The method may include forming an interconnect structure including a first segment and a second segment, wherein the second segment may extend vertically from the first segment; and coupling the interconnect structure to a package substrate having at least one opening extending through the package substrate, wherein the first segment may extend under a bottom surface of the package substrate and may further extend beyond a footprint of the package substrate, and wherein the second segment may extend at least partially through the at least one opening of the package substrate.

The present disclosure generally relates to a computing device. The computing device may include a printed circuit board; a package substrate including at least one opening extending through the package substrate; an interconnect structure including a first segment and a second segment; a die coupled to a top surface of the package substrate and a top surface of the second segment; and a plurality of chiplets coupled to the package substrate and the interconnect structure through the die. The first segment may extend between the package substrate and the printed circuit board and may further extend beyond a footprint of the package substrate. The second segment may extend vertically from the first segment and may extend at least partially through the at least one opening of the package substrate.

To more readily understand and put into practice the aspects of the present semiconductor package, particular aspects will now be described by way of examples and not limitations, and with reference to the figures. For the sake of brevity, duplicate descriptions of features and properties may be omitted.

It should be understood that the terms “on”, “under”, “top”, “bottom”, etc., when used in this description are used for convenience and to aid understanding of relative positions or directions, and not intended to limit the orientation of any device, or structure or any part of any device or structure.

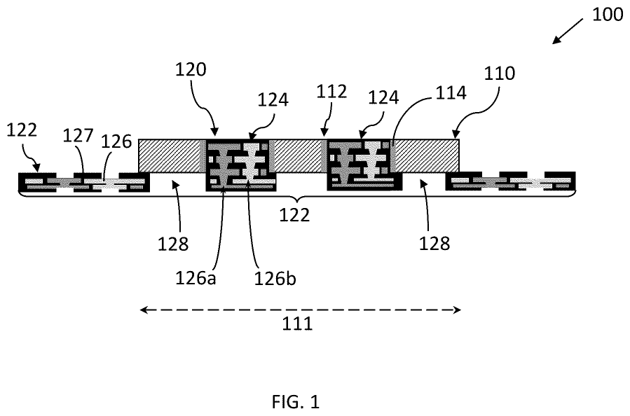

In an aspect shown in FIG. 1, a device 100 of the present disclosure is shown in a cross-sectional view layout, including a package substrate 110 including at least one opening 112 extending through the package substrate 110, and an interconnect structure 120 including a first segment 122 and a second segment 124. The first segment 122 may extend under a bottom surface of the package substrate 110 and may further extend beyond a footprint 111 of the package substrate 110. The second segment 124 may extend vertically from the first segment 122 and may extend at least partially through the at least one opening 112 of the package substrate 110.

According to various aspects of the present disclosure, the first segment 122 may extend horizontally along the bottom surface of the package substrate 110, and the second segment 124 may extend vertically into the at least one opening 112 of the package substrate 110. In this manner, the interconnect structure 120 may be integrated with the package substrate 110, to provide an improved interconnect network (e.g., power delivery network) for a semiconductor package. In an aspect, the second segment 124 may be integral with the first segment 122. In another aspect, the second segment 124 may be attached to the first segment 122.

The interconnect structure 120 may be attached to the package substrate 110 through an epoxy polymer layer 114 in the at least one opening 112 of the package substrate 110. As shown in FIG. 1, the epoxy polymer layer 114 may fill a gap between the second segment 124 and the package substrate 110.

In the aspects shown in FIG. 1, the package substrate 110 may include two openings 112, and the second segment 124 may include two sub-segments 124 extending into the two openings 112, respectively. It is understood that the package substrate 110 may include only one opening or more than two openings, and the second segment 124 may correspondingly include one sub-segment or more than two sub-segments extending into the respective opening, according to various aspects of the present disclosure.

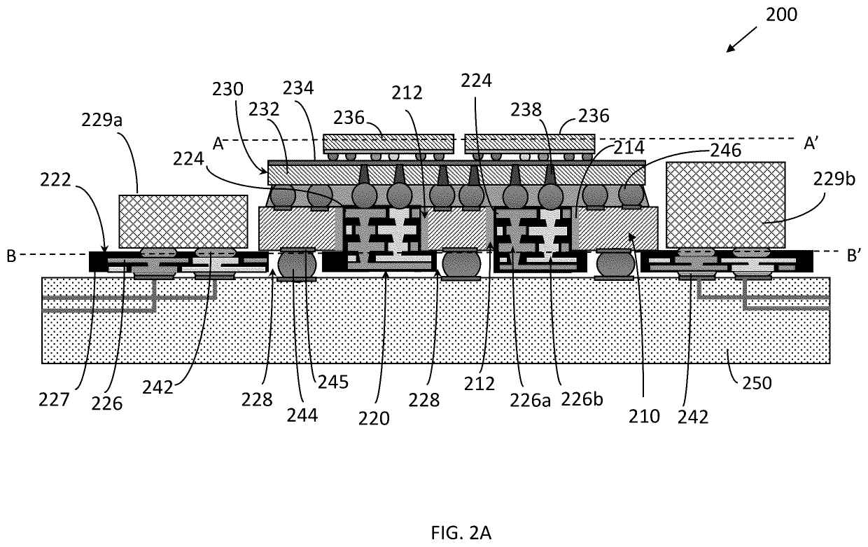

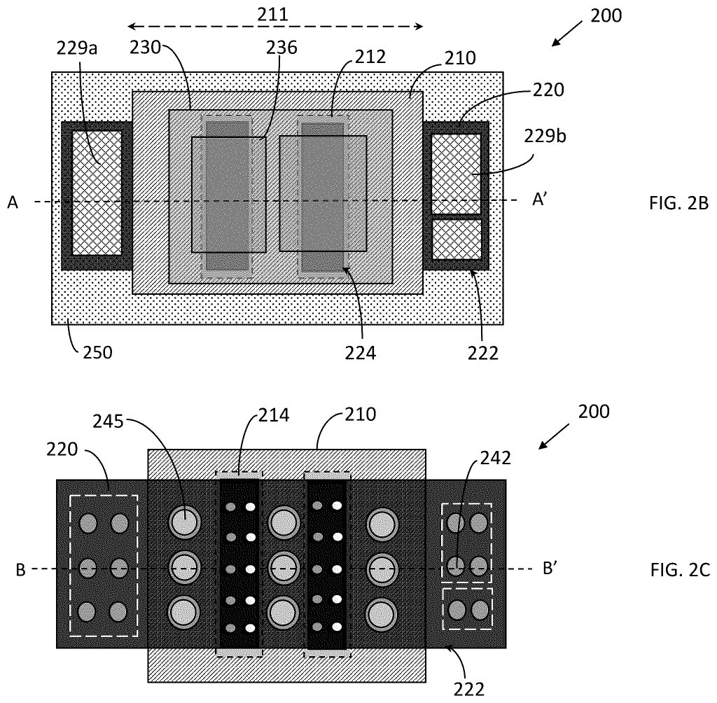

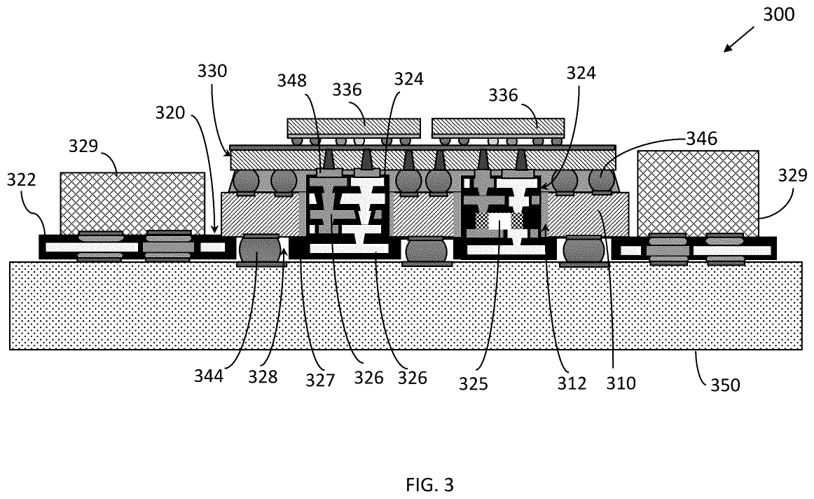

The interconnect structure 120 may include at least one conductive plane 126 isolated by a dielectric layer 127. The dielectric layer 127 may include an epoxy mold layer, a polyimide layer, or a silicone layer. The at least one conductive plane 126 may include any suitable conductive material, for example, a metal plane. The at least one conductive plane 126 may extend horizontally between the top surface and the bottom surface of the interconnect structure 120. In various aspects, the at least one conductive plane 126 may be arranged in both the first segment 122 and the second segment 124, and may be coupled with vias and contact pads in the interconnect structure 120 for signal or power delivery between a bottom end and a top end of the interconnect structure 120. Accordingly, the interconnect structure 120 may be configured to deliver signal or power between the bottom end of the first segment 122 which may be coupled to a printed circuit board and the top end of the second segment 124 which may be coupled to one or more dies or chips, as shown in FIG. 2A and FIG. 3 below.

In various aspects, the at least one conductive plane 126 may include at least one of a reference plane coupled to a reference voltage, a power plane coupled to a power (Vcc) supply voltage, or a signal plane configured for signal transmission. The reference voltage may be a ground (Vss) reference voltage, and the reference plane may be referred to as a ground plane accordingly.

In an aspect illustrated in FIG. 1, the at least one conductive plane 126 may include a first group 126a and a second group 126b. In an example, the first group 126a may include one or more ground planes, and the second group 126b may include one or more power planes. The interconnect structure 120 may be referred to as a power delivery structure accordingly. In another example, the first group 126a may include one or more ground planes, and the second group 126b may include one or more signal planes. The interconnect structure 120 may be referred to as a signal interconnect structure accordingly.

In another aspect, the at least one conductive plane 126 may include three groups, wherein the three groups may include one or more ground planes, power planes and signal planes, respectively. In this manner, the interconnect structure 120 may be configured for both power delivery and signal interconnect. In a further aspect, the at least one conductive plane 126 may include only one group including one of a ground plane, a power plane or a signal plane.

In various aspects, the power plane may be coupled to the reference plane through one or more decoupling capacitors. In an aspect, the second segment 124 may include a decoupling capacitor (as shown in FIG. 3 below) having one terminal coupled to the reference plane and having another terminal coupled to the power plane. The decoupling capacitor may include, for example, a multilayer ceramic capacitor or a silicon capacitor coupling the ground plane to the power plane to suppress PDN peak impedance for power supply noise reduction. In a further aspect, the first segment 122 may also include a decoupling capacitor coupled to the reference plane and the power plane.

The package substrate 110 may include an organic package substrate, a ceramic package substrate or a glass substrate. The package substrate 110 may include contact pads, electrical interconnects and routings, and other features, for signal routing and electrical connection to various devices and components. In an example, the package substrate 110 may include one or more signal planes for signal transmission, e.g., when the interconnect structure 120 is configured for power delivery. In another example, the package substrate 110 may include one or more power planes for power delivery, e.g., when the interconnect structure 120 is configured for signal interconnect. It is understood that the package substrate 110 and the interconnect structure 120 may be configured to deliver the same or different types of voltages or signals.

The second segment 124 may be coupled to the first segment 122. In an aspect, the conductive planes 126 in the first segment 122 and the second segment 124 may be coupled with each other through vias and contact pads, for power delivery or signal interconnect between the first segment 122 and the second segment 124. Accordingly, power delivery or signal transmission may be facilitated between the bottom end of the first segment 122 which may be coupled to a printed circuit board and the top end of the second segment 124 which may be coupled to one or more dies or chiplets.

According to various aspects, the first segment 122 may include a plurality of openings 128 extending through the first segment 122. The plurality of openings 128 may be arranged under the bottom surface of the package substrate 110 and within the footprint 111 of the package substrate 110. The plurality of openings 128 may be configured to accommodate solder bumps to couple the package substrate 110 to a printed circuit board as shown in FIG. 2A and FIG. 3 below.

Although the first segment 122 is shown as four pieces separated by the plurality of openings 128 in the cross-sectional view of FIG. 1, it is understood that the four pieces may be connected at areas around the openings 128. The first segment 122 may be a continuous structure as shown in FIG. 2B and FIG. 2C below.

According to various aspects, a thickness of the first segment 122 may be smaller than a thickness of the second segment 124. In an example, the thickness of the first segment 122 may be ranging from about 50 nm to about 300 nm, and the thickness of the second segment 124 may be ranging from about 100 nm to about 1.5 mm. The second segment 124 with a greater thickness may be configured to accommodate more conductive planes to provide more electrical routings, e.g., between a printed circuit board and chiplets which may be attached to opposite sides of the interconnect structure 120, respectively. The second segment 124 with a greater thickness may also be configured to accommodate one or more components, e.g., decoupling capacitors.

In an aspect, the second segment 124 may extend partially through the at least one opening 112 of the package substrate 110, wherein the thickness of the second segment 124 may be smaller than the thickness of the package substrate 110. In another aspect, the second segment 124 may extend entirely through the at least one opening 112 of the package substrate 110, wherein the thickness of the second segment 124 may be equal to the thickness of the package substrate 110. In a further aspect, the second segment 124 may further extend beyond the at least one opening 112 of the package substrate 110 and beyond a top surface of the package substrate 110 to achieve enhanced signal integrity/power delivery network for improved performance, as shown in FIG. 3 below.

The device 100 with the package substrate 110 and the interconnect structure 120 according to various aspects above may provide a base structure, and may be referred to as an electronic package 100. The electronic package 100 may be assembled with one or more semiconductive die or chiplets to form a semiconductor package.

According to various aspects of the present disclosure, the device 100 may further include one or more components coupled to a top surface of the first segment 122 outside the footprint 111 of the package substrate 110, as shown in FIG. 2A and FIG. 3 below. The space outside the footprint 111 of the package substrate 110 may thus be better utilized for improved electrical performance. In an aspect, the components may include a passive component. The passive component may include an inductor, a voltage regulator, or a power management integrated circuit (PMIC). In another aspect, the components may include a connector, e.g., a Serializer/Deserializer (SerDes) Ethernet switch or a Peripheral Component Interconnect Express (PCIe) connector.

According to various aspects of the present disclosure, the device 100 may further include a die coupled to a top surface of the package substrate 110 and a top surface of the second segment 124, as shown in FIG. 2A and FIG. 3 below. The die may include a die substrate and a redistribution layer (RDL) on the die substrate. The redistribution layer may include one or more metal layers isolated by a dielectric layer, wherein metal interconnection may be formed in the metal layers to route electrical signals between various chiplets which may be attached to the die. In an aspect, the redistribution layer may include a signal layer for signal transmission, a ground (Vss) layer, and/or a power (Vcc) layer. The die substrate may include a silicon interposer with through-silicon-vias (TSVs) for electrical interconnection. Accordingly, chiplets attached to the die may be coupled to the package substrate 110 and the interconnect structure 120 through the redistribution layer and the die substrate. The die substrate may further include one or more components in a further aspect.

According to various aspects of the present disclosure, the device 100 may further include a plurality of chiplets coupled to the package substrate 110 and the interconnect structure 120 through the die, as shown in FIG. 2A and FIG. 3 below. The chiplets may be coupled to the redistribution layer at the top side of the die, and the package substrate 110 and the interconnect structure 120 may be coupled to the die substrate at the bottom side of the die. The plurality of chiplets may include one or more of a central processing unit (CPU), a neural processing unit (NPU), a deep learning processor (DLP), a graphic processing unit (GPU), a system-on-chip (SOC), a memory device, or an I/O tile.

The electronic package 100 with the package substrate 110 and the interconnect structure 120, when assembled with the die and the chiplets according to various aspects above, may form a semiconductor package or assembly which may be further attached to a printed circuit board.

According to various aspects of the present disclosure, a printed circuit board may be coupled to the interconnect structure 120 and the package substrate 110 to form a computing device, as shown in FIG. 2A and FIG. 3 below. The first segment 122 may extend between the package substrate 110 and the printed circuit board.

In the aspects shown in FIG. 1, the first segment 122 may include surface openings on the top surface and/or the bottom surface of the first segment 122. The surface openings at the bottom surface of the first segment 122 may be configured to accommodate solder layers for coupling the printed circuit board to the first segment 122. The surface openings at the top surface of the first segment 122 may be configured to accommodate solder layers for coupling the one or more components to the first segment 122.

FIG. 2A shows a cross-sectional view of a device 200 according to a further aspect of the present disclosure. FIG. 2B shows a top view layout of the device 200 along line A-A′ of FIG. 2A, and FIG. 2C shows a bottom view layout of the device 200 along line B-B′ of FIG. 2A.

Many of the aspects of the device 200 are the same or similar to those of the device 100. For the sake of brevity, duplicate descriptions of features and properties are omitted. Accordingly, it will be understood that the descriptions of any feature and/or property relating to FIGS. 2A to 2C that are the same or similar to a feature and/or property in FIG. 1 will have those descriptions be applicable hereinbelow as well.

In the aspect shown in FIG. 2A, a device 200 of the present disclosure is shown in a cross-sectional view layout, including a package substrate 210 including at least one opening 212 extending through the package substrate 210, and an interconnect structure 220 including a first segment 222 and a second segment 224. The first segment 222 may extend under a bottom surface of the package substrate 210, and may further extend beyond a footprint 211 of the package substrate 210 as shown in FIG. 2B. The second segment 224 may extend vertically from the first segment 222 and may extend at least partially through the at least one opening 212 of the package substrate 210.

The first segment 222 may extend horizontally along the bottom surface of the package substrate 210, and the second segment 224 may extend vertically into the at least one opening 212 of the package substrate 210. In this manner, the interconnect structure 220 may be integrated with the package substrate 210 to provide an improved interconnect network (e.g., power delivery network) for a semiconductor package. In an aspect, the second segment 224 may be integral with the first segment 222. In another aspect, the second segment 224 may be attached to the first segment 222.

The interconnect structure 220 may be attached to the package substrate 210 through an epoxy polymer layer 214 in the at least one opening 212 of the package substrate 210. As shown in FIG. 2A, the epoxy polymer layer 214 may fill a gap between the second segment 224 and the package substrate 210. In the aspects shown in FIG. 2A and FIG. 2B, the package substrate 210 may include two openings 212, and the second segment 224 may include two sub-segments 224 extending into the two openings 212, respectively. It is understood that the package substrate 210 may include only one opening or more than two openings, and the second segment 224 may correspondingly include one sub-segment or more than two sub-segments extending into the respective opening, according to various aspects.

In various aspects of FIG. 2A, the device 200 may further include a die 230 coupled to a top surface of the package substrate 210 and a top surface of the second segment 224. The die 230 may include a die substrate 232 and a redistribution layer (RDL) 234 on the die substrate 232. The die substrate 232 may be coupled to the package substrate 210 and the second segment 224 through solder bumps 246.

In various aspects of FIG. 2A, the device 200 may further include a plurality of chiplets 236 coupled to the package substrate 210 and the interconnect structure 220 through the die 230. The chiplets 236 may be coupled to the redistribution layer 234 at a top side of the die 230. The package substrate 210 and the interconnect structure 220 may be coupled to the die substrate 232 at a bottom side of the die 230. The plurality of chiplets 236 may include one or more of a central processing unit (CPU), a neural processing unit (NPU), a deep learning processor (DLP), a graphic processing unit (GPU), a system-on-chip (SOC), a memory device, or an I/O tile.

The redistribution layer 234 may include one or more metal layers isolated by a dielectric layer, wherein metal interconnection may be formed in the metal layers to route electrical signals between various chiplets 236 attached to the die 230. In an aspect, the redistribution layer 234 may include a signal layer for signal transmission, a ground (Vss) layer, and/or a power (Vcc) layer. The die substrate 232 may include a silicon interposer with through-silicon-vias (TSVs) 238 for electrical interconnection. Accordingly, the chiplets 236 may be coupled to the package substrate 210 and the interconnect structure 220 through the redistribution layer 234 and the die substrate 232. The die substrate may further include one or more components in a further aspect.

The package substrate 210 and the interconnect structure 220 according to various aspects above may provide a base structure similar to the electronic package 100, and when assembled with the die 230 and the chiplets 236, may form a semiconductor package or assembly 200 which may be further attached to a printed circuit board.

According to various aspects of FIG. 2A, the device 200 may further include a printed circuit board 250 coupled to the interconnect structure 220 and the package substrate 210. The first segment 222 may extend between the package substrate 210 and the printed circuit board 250. In other words, the first segment 222 may be arranged or sandwiched in between the package substrate 210 and the printed circuit board 250. The device 200 including the above-mentioned semiconductor package attached to the printed circuit board may be referred to as a computing device.

In an aspect, the printed circuit board 250 may be coupled to the first segment 222 through solder layers 242, wherein the bottom surface of the first segment 222 may include surface openings (as shown in FIG. 1) to accommodate the solder layers 242.

In a further aspect, the printed circuit board 250 may be coupled to the package substrate 210 through solder bumps 244, e.g., ball grid array (BGA) solder bumps, and associated BGA pads 245, as shown in FIG. 2A and FIG. 2C.

Similar to FIG. 1, the first segment 222 may include a plurality of openings 228 extending through the first segment 222. The plurality of openings 228 may be arranged under the bottom surface of the package substrate 210 and within the footprint 211 of the package substrate 210. The plurality of openings 228 may be configured to accommodate solder bumps 244 to couple the package substrate 210 to the printed circuit board 250 as shown in FIG. 2A.

Although the first segment 222 is shown as four pieces separated by the plurality of openings 228 in the cross-sectional view of FIG. 2A, it is understood that the four pieces may be connected at areas around the openings 228. The first segment 222 may be a continuous structure as shown in FIG. 2B and FIG. 2C.

Similar to FIG. 1, the interconnect structure 220 may include at least one conductive plane 226 isolated by a dielectric layer 227. The dielectric layer 227 may include an epoxy mold layer, a polyimide layer, or a silicone layer. The at least one conductive plane 226 may include any suitable conductive material, e.g., a metal plane. The at least one conductive plane 226 may extend horizontally between the top surface and the bottom surface of the interconnect structure 220. In various aspects, the at least one conductive plane 226 may be arranged in both the first segment 222 and the second segment 224, and may be coupled with vias and contact pads in the interconnect structure 220 for signal interconnect or power delivery between a bottom end and a top end of the interconnect structure 220. Accordingly, the interconnect structure 220 may be configured to facilitate signal transmission and/or power delivery between the bottom end of the first segment 222 which may be coupled to the printed circuit board 250 and the top end of the second segment 224 which may be coupled to one or more dies 230 and chiplets 236, as shown in FIG. 2A.

In various aspects, the at least one conductive plane 226 may include at least one of a reference plane coupled to a reference voltage (e.g., a ground plane coupled to a ground (Vss) reference voltage), a power plane coupled to a power (Vcc) supply voltage, or a signal plane configured for signal transmission.

Similar to FIG. 1, the at least one conductive plane 226 may include a first group 226a and a second group 226b. In an example, the first group 226a may include one or more ground planes, and the second group 226b may include one or more power planes. The interconnect structure 220 may be referred to as a power delivery structure accordingly. In another example, the first group 226a may include one or more ground planes, and the second group 226b may include one or more signal planes. The interconnect structure 220 may be referred to as a signal interconnect structure accordingly.

In another aspect, the at least one conductive plane 226 may include three groups, wherein the three groups may include one or more ground planes, power planes and signal planes, respectively. Accordingly, the interconnect structure 220 may be configured for both signal transmission and power delivery. In a further aspect, the at least one conductive plane 226 may include only one group including one of a ground plane, a power plane or a signal plane.

In various aspects, the power plane may be coupled to the reference plane through one or more decoupling capacitors. The first segment 222 and/or the second segment 224 may include a decoupling capacitor (as shown in FIG. 3 below) having one terminal coupled to the reference plane and having another terminal coupled to the power plane.

Similar to FIG. 1, the package substrate 210 may include an organic package substrate, a ceramic package substrate or a glass substrate, which may include contact pads, electrical interconnects and routings, and other features for signal routing and electrical connection to various devices and components. In an example, the package substrate 210 may include one or more signal planes for signal transmission, e.g., when the interconnect structure 220 is configured for power delivery. In another example, the package substrate 210 may include one or more power planes for power delivery, e.g., when the interconnect structure 220 is configured for signal interconnect. The package substrate 210 and the interconnect structure 220 may be configured to deliver the same or different types of voltages or signals.

In various aspects, the second segment 224 may be coupled to the first segment 222. In an aspect, the conductive planes 226 in the first segment 222 and the second segment 224 may be coupled with each other through vias and contact pads, for power delivery or signal interconnect between the first segment 222 and the second segment 224. Accordingly, power delivery or signal transmission may be facilitated between the bottom end of the first segment 222 which may be coupled to the printed circuit board 250 and the top end of the second segment 224 which may be coupled to the die 230 and chiplets 236.

According to various aspects, a thickness of the first segment 222 may be smaller than a thickness of the second segment 224. In an example, the thickness of the first segment 222 may be ranging from about 50 μm to about 300 μm, and the thickness of the second segment 224 may be ranging from about 100 μm to about 1.5 mm. The second segment 224 with a greater thickness may be configured to accommodate more conductive planes to provide more electrical routings, e.g., between the printed circuit board 250 and chiplets 236 attached to opposite sides of the interconnect structure 220. The second segment 224 with a greater thickness may also be configured to accommodate one or more components, e.g., decoupling capacitors.

In an aspect, the second segment 224 may extend entirely through the at least one opening 212 of the package substrate 210, wherein the thickness of the second segment 224 may be equal to the thickness of the package substrate 210 as shown in FIG. 2A. In another aspect, the second segment 224 may extend partially through the at least one opening 212 of the package substrate 210, wherein the thickness of the second segment 224 may be smaller than the thickness of the package substrate 210. In a further aspect, the second segment 224 may further extend beyond the at least one opening 212 of the package substrate 210 and beyond a top surface of the package substrate 210 to achieve enhanced signal integrity/power delivery network for improved performance, as shown in FIG. 3 below.

According to various aspects of the present disclosure, the device 200 may further include one or more components 229a, 229b coupled to a top surface of the first segment 222 outside the footprint 211 of the package substrate 210, as shown in FIG. 2A. The components 229a, 229b may be coupled to the top surface of the first segment 222 through solder layers 242, wherein the top surface of the first segment 222 may include surface openings (as shown in FIG. 1) to accommodate the solder layers 242. Accordingly, the space outside the footprint 211 of the package substrate 210 in the computing device 200 may be better utilized. In an aspect, the components 229a, 229b may include a passive component, examples of which may include but are not limited to an inductor, a voltage regulator, or a power management integrated circuit (PMIC). For example, the component 229a may be a voltage regulator, and the component 229b may be an inductor. In another aspect, the components may include a connector, e.g., a Serializer/Deserializer (SerDes) Ethernet switch or a Peripheral Component Interconnect Express (PCIe) connector 229b.

Various aspects of FIGS. 2A to 2C provide a computing device or semiconductor package 200 with integrated power/signal interconnect structure for improved computing performance and device miniaturization.

FIG. 3 shows a cross-sectional view of a device 300 according to a further aspect of the present disclosure.

Many of the aspects of the device 300 are the same or similar to those of the devices 100, 200. For the sake of brevity, duplicate descriptions of features and properties are omitted. Accordingly, it will be understood that the descriptions of any feature and/or property relating to FIG. 3 that are the same or similar to a feature and/or property in FIG. 1 and FIGS. 2A to 2C will have those descriptions be applicable hereinbelow as well.

In the aspect shown in FIG. 3, a device 300 of the present disclosure is shown in a cross-sectional view layout, including a package substrate 310 including at least one opening 312 extending through the package substrate 310, an interconnect structure 320 including a first segment 322 and a second segment 324, and a printed circuit board 350 coupled to the interconnect structure 320 and the package substrate 310. The first segment 322 may extend between the package substrate 310 and the printed circuit board 350, and may further extend beyond a footprint of the package substrate 310. The second segment 324 may extend vertically from the first segment 322 and may extend at least partially through the at least one opening 312 of the package substrate 310.

In the aspect shown in FIG. 3, the device 300 may further include a die 330 coupled to a top surface of the package substrate 310 and a top surface of the second segment 324. The device 300 may further include a plurality of chiplets 336 coupled to the package substrate 310 and the interconnect structure 320 through the die 330. Accordingly, a semiconductor package 300 may be formed when the die 330 and the chiplets 336 are coupled with the package substrate 310 and the interconnect structure 320, and may be further coupled with the printed circuit board 350 to form a computing device 300.

Similar to FIG. 2A, the printed circuit board 350 may be coupled to the first segment 322 through solder layers, wherein the bottom surface of the first segment 322 may include surface openings (as shown in FIG. 1) to accommodate the solder layers. In a further aspect, the printed circuit board 350 may be coupled to the package substrate 310 through solder bumps 344, e.g., BGA solder bumps, and associated BGA pads, similar to FIG. 2A and FIG. 2C.

The first segment 322 may include a plurality of openings 328 extending through the first segment 322. The plurality of openings 328 may be arranged under the bottom surface of the package substrate 310 and within the footprint of the package substrate 310. The openings 328 may be provided to allow for a coupling between the package substrate 310 and the printed circuit board 350, for example, configured to accommodate the solder bumps 344 to couple the package substrate 310 to the printed circuit board 350 as shown in FIG. 3.

Similar to the description above, although the first segment 322 is shown as four pieces separated by the plurality of openings 328 in the cross-sectional view of FIG. 3, the four pieces may be a continuous structure connected at areas around the openings 328, similar to the aspects shown in FIG. 2B and FIG. 2C.

The interconnect structure 320 may be attached to the package substrate 310 through an epoxy polymer layer in the at least one opening 312 of the package substrate 310, wherein the epoxy polymer layer may fill a gap between the second segment 324 and the package substrate 310. In various aspects, the package substrate 310 may include one or more openings 312, and the second segment 324 may correspondingly include one or more sub-segments extending into the respective openings 312.

In the aspect shown in FIG. 3, the second segment 324 may further extend beyond the at least one opening 312 of the package substrate 310 and beyond a top surface of the package substrate 310, so as to achieve enhanced signal integrity/power delivery network for improved performance. The thickness of the second segment 324 may be greater than the thickness of the package substrate 310.

In the aspect shown in FIG. 3, the second segment 324 may be coupled to the die 330 through a solder layer 348, where a space between the second segment 324 and the die 330 may be smaller than a space between the package substrate 310 and the die 330. The package substrate 310 may be coupled to the die 330 through solder bumps 346, similar to FIG. 2A above. The solder bumps 346 and the solder layers 348 may be covered by an epoxy polymer layer, similar to the epoxy polymer layer filled in the package substrate openings 312.

Similar to the aspects of FIG. 2A, the die 330 may include a die substrate and a redistribution layer (RDL) on the die substrate. The chiplets 336 may be coupled to the redistribution layer at the top side of the die 330. The package substrate 310 and the interconnect structure 320 may be coupled to the die substrate at the bottom side of the die 330. The plurality of chiplets 336 may include one or more of a central processing unit (CPU), a neural processing unit (NPU), a deep learning processor (DLP), a graphic processing unit (GPU), a system-on-chip (SOC), a memory device, or an I/O tile.

The redistribution layer of the die 330 may include one or more metal layers isolated by a dielectric layer, wherein metal interconnection may be formed in the metal layers to route electrical signals between various chiplets 336 attached to the die 330. In an aspect, the redistribution layer 334 may include one or more of a signal layer for signal transmission, a ground (Vss) layer, or a power (Vcc) layer. The die substrate may include a silicon interposer with TSVs for electrical interconnection. Accordingly, the chiplets 336 may be coupled to the package substrate 310 and the interconnect structure 320 through the die 330.

Similar to various aspects above, the second segment 324 may be integral with the first segment 322, or may be attached to the first segment 322. The first segment 322 may extend horizontally under and along the bottom surface of the package substrate 310, and the second segment 324 may extend vertically into the at least one opening 312 of the package substrate 310. In this manner, the interconnect structure 320 may be integrated with the package substrate 310 to provide an improved interconnect network (e.g., signal transmission/power delivery network) for the semiconductor package/computing device 300.

Similar to FIG. 1 and FIG. 2A above, the interconnect structure 320 may include at least one conductive plane 326 isolated by a dielectric layer 327. In various aspects, the at least one conductive plane 326 may be arranged in both the first segment 322 and the second segment 324, and may be coupled with vias and contact pads in the interconnect structure 320 for signal interconnect or power delivery between a bottom end and a top end of the interconnect structure 320. In other words, the second segment 324 may be coupled to the first segment 322. Accordingly, the interconnect structure 320 may be configured to facilitate signal transmission and/or power delivery between the bottom end of the first segment 322 which may be coupled to the printed circuit board 350 and the top end of the second segment 324 which may be coupled to the die 330 and chiplets 336.

In various aspects, the at least one conductive plane 326 may include at least one of a reference plane coupled to a reference voltage (e.g., a ground plane coupled to a ground (Vss) reference voltage), a power plane coupled to a power (Vcc) supply voltage, or a signal plane configured for signal transmission. In various aspects, the power plane may be coupled to the reference plane through one or more decoupling capacitors.

Similar to FIG. 1 and FIG. 2A, the at least one conductive plane 326 may include one or more groups, wherein the one or more groups may include one or more ground planes, power planes and signal planes, respectively. Accordingly, the interconnect structure 320 may be configured for both signal transmission and/or power delivery.

Similar to FIG. 1 and FIG. 2A, the package substrate 310 may include one or more signal planes for signal transmission, e.g., when the interconnect structure 320 is configured for power delivery in an example. In another example, the package substrate 310 may include one or more power planes for power delivery, e.g., when the interconnect structure 320 is configured for signal interconnect. The package substrate 310 and the interconnect structure 320 may be configured to deliver the same or different types of voltages or signals.

According to various aspects, a thickness of the first segment 322 may be smaller than a thickness of the second segment 324. The second segment 324 with a greater thickness may be configured to accommodate more conductive planes to provide more electrical routings. The second segment 324 with a greater thickness may also be configured to accommodate one or more components, e.g., decoupling capacitors.

In the aspects of FIG. 3, the second segment 324 may include a decoupling capacitor 325 having one terminal coupled to the reference plane and having another terminal coupled to the power plane. The decoupling capacitor 325 may include, for example, a multilayer ceramic capacitor or a silicon capacitor coupling the ground plane to the power plane to suppress PDN peak impedance for power supply noise reduction. In a further aspect, the first segment 322 may also include a decoupling capacitor coupled to the reference plane and the power plane.

Similar to various aspects of FIG. 2A above, one or more components 329 may be coupled to a top surface of the first segment 322 outside the footprint of the package substrate 310. The components 329 may be coupled to the top surface of the first segment 322 through solder layers, wherein the top surface of the first segment 322 may include surface openings (as shown in FIG. 1) to accommodate the solder layers.

According to various aspects of FIG. 3 above, a computing device or semiconductor package 300 with integrated power/signal interconnect structure is provided for improved computing performance and device miniaturization.

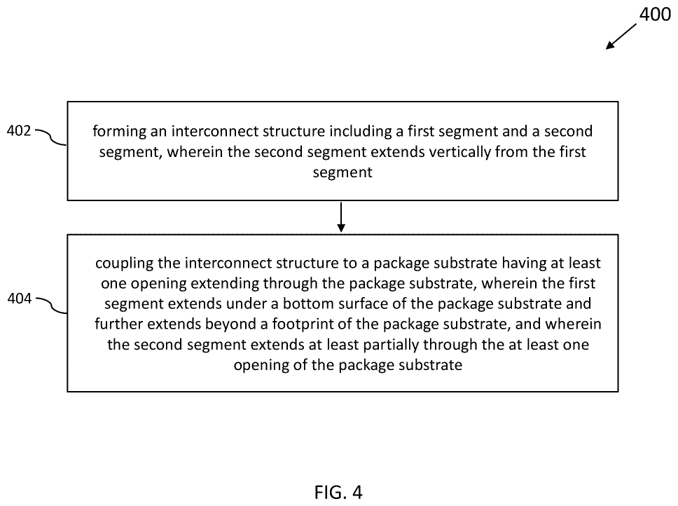

FIG. 4 shows a flowchart 400 illustrating a method of forming a device, such as the device 100, 200, 300 of FIGS. 1, 2A-2C and 3, according to an aspect of the present disclosure. Various aspects described with reference to FIGS. 1, 2A-2C and 3 may be similarly applied for the method of FIG. 4.

At 402, an interconnect structure including a first segment and a second segment may be formed, wherein the second segment may extend vertically from the first segment.

At 404, the interconnect structure may be coupled to a package substrate having at least one opening extending through the package substrate. The first segment may extend under a bottom surface of the package substrate and may further extend beyond a footprint of the package substrate. The second segment may extend at least partially through the at least one opening of the package substrate.

In an aspect, the method may further include coupling a die to a top surface of the package substrate and a top surface of the second segment.

In a further aspect, the method may further include coupling a plurality of chiplets to the package substrate and the interconnect structure through the die. The chiplets may be coupled to a top surface of the die. The package substrate and the interconnect structure may be coupled to a bottom surface of the die.

According to a further aspect, the method may further include coupling the package substrate and the first segment of the interconnect structure to a printed circuit board.

It will be understood that the operations described above relating to FIG. 4 are not limited to this particular order. Any suitable, modified order of operations may be used.

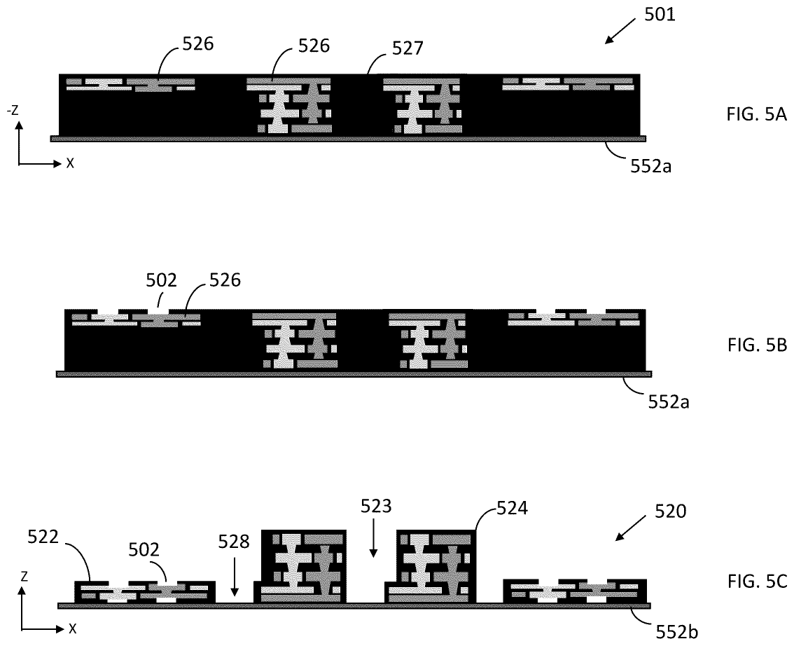

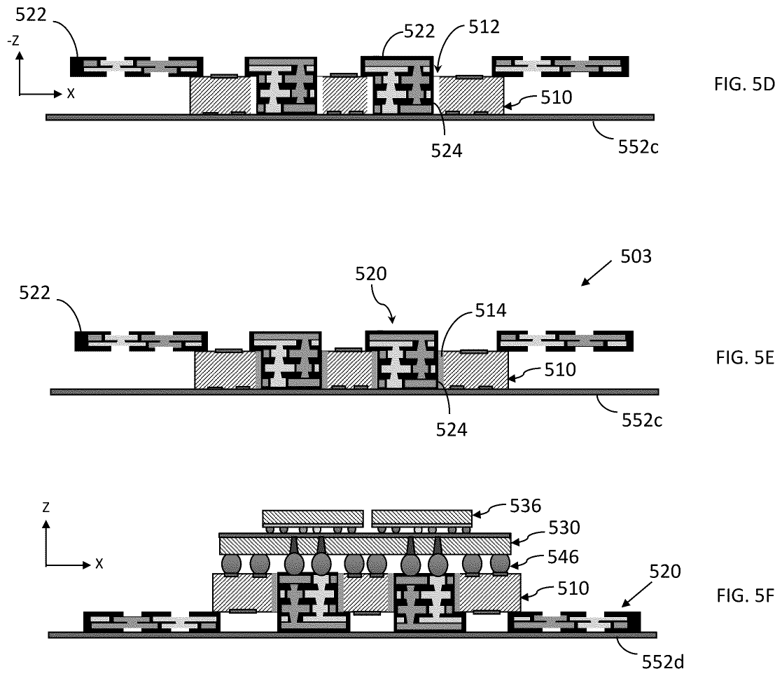

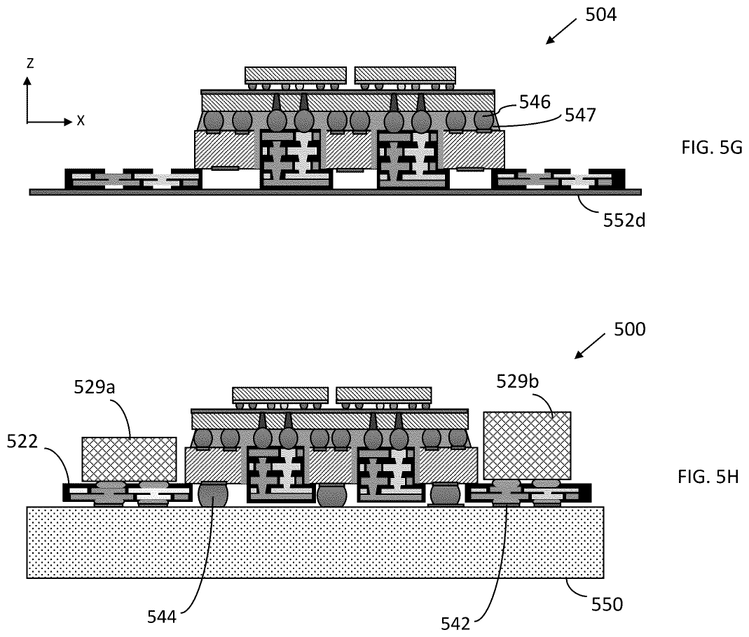

FIGS. 5A through 5H show cross-sectional views directed to an exemplary process flow for a method of making a device (e.g., the device 100, 200, 300) according to an aspect of the present disclosure. Various aspects described with reference to FIGS. 1, 2A-2C, and 3 may be similarly applied for the process flow of FIG. 5A-5H.

In FIG. 5A, an initial interconnection structure 501 is provided or formed, e.g., through a compression/transfer/injection molding process, and an electroplating/etching process. The initial interconnection structure 501 may include multiple conductive layers 526 (e.g., metal layers) in a dielectric/mold layer 527. The initial interconnection structure 501 may be attached on a first carrier 552a, with its Z-axis surface in contact with the first carrier 552a.

In FIG. 5B, the initial interconnection structure 501 may be processed to form one or more surface openings 502 on the −Z-axis surface of the initial interconnection structure 501, e.g., through a mechanical drilling or a laser etching process. The surface openings 502 may expose the metal layers 526 or the contact pads coupled to the metal layers 526, and may be configured to accommodate solder layers for coupling with a printed circuit board.

In FIG. 5C, the structure of FIG. 5B may be flipped, with its −Z-axis surface attached to and in contact with a second carrier 552b. Portions of the dielectric/mold layer 527 may be removed to form a first segment 522 and a second segment 524, e.g., through a mechanical drilling or a laser etching process, wherein the first segment 522 may extend horizontally and the second segment 524 may extend vertically from the first segment 522. One or more surface openings 502 may be formed on the Z-axis surface of the first segment 522, e.g., through a mechanical drilling or a laser etching process, to expose the metal layers or the contact pads coupled to the metal layers 526 in the first segment 522. The surface openings 502 on the Z-axis surface of the first segment 522 may be configured to accommodate solder layers for coupling with one or more components.

In the aspect of FIG. 5C, one or more openings 528 may be formed extending through the first segment 522. One or more further openings 523 may be formed next to the second segment 524, which may provide a space for attaching with a package substrate as shown in FIG. 5D below. FIG. 5C may provide an interconnect structure 520, which may be similar to the interconnect structure 120, 220, 320 of FIGS. 1, 2A-2C and 3 described above.

In FIG. 5D, the interconnect structure 520 may be attached onto a package substrate 510, e.g., through a vacuum pick and place process, wherein one or more package openings 512 may be formed extending through the package substrate 510. The second segment 524 may extend into the package openings 512. The Z-axis surface of the interconnect structure 520 and the package substrate 510 may be attached to a third carrier 552c.

In FIG. 5E, an epoxy polymer layer 514 may be formed in the package opening 512 of FIG. 5D, e.g., through an epoxy dispense or cure process. Accordingly, the interconnect structure 520 may be attached to the package substrate 510. The structure 503 of FIG. 5E may be similar to the electronic package 100 of FIG. 1 above, and accordingly the electronic package 100 may be manufactured according to the processes of FIGS. 5A-5E according to various aspects. The structure 503 of FIG. 5E may be flipped over and assembled with a die, a chiplet and a printed circuit board to form the semiconductor package/computing device 200, 300 of FIGS. 2A and 3 above.

In FIG. 5F, the structure 503 of FIG. 5E may be flipped, and the −Z-axis surface of the interconnect structure 520 may be attached onto a fourth carrier 552d. A silicon die 530 and stacked chiplets 536 may be attached to the interconnect structure 520 and the package substrate 510 via solder bumps 546, e.g., through a solder reflow or thermal compression bonding process.

In FIG. 5G, a further epoxy layer or underfill layer 547 may be dispensed on the solder bumps 546, e.g., through a dispense or cure process. Accordingly, a semiconductor package 504 in which the die and chiplets are assembled with the package substrate and the interconnect structure is provided.

In FIG. 5H, one or more components 529a, 529b may be attached on the first segment 522, and the package 504 of FIG. 5G may be assembled to a printed circuit board 550 via solder layers 542 and solder bumps 544, e.g., through surface mounting and solder reflow processes. The structure 500 of FIG. 5H may be similar to the computing device 200 of FIG. 2A above, and accordingly the computing device 200 may be manufactured according to the processes of FIGS. 5A-5H.

FIGS. 5A-5H above illustrate an exemplary process flow to manufacture a device with integrated interconnect structure for multi-chip package applications. The operation order described above may be interchangeable to achieve optimum assembly yield and/or throughput time.

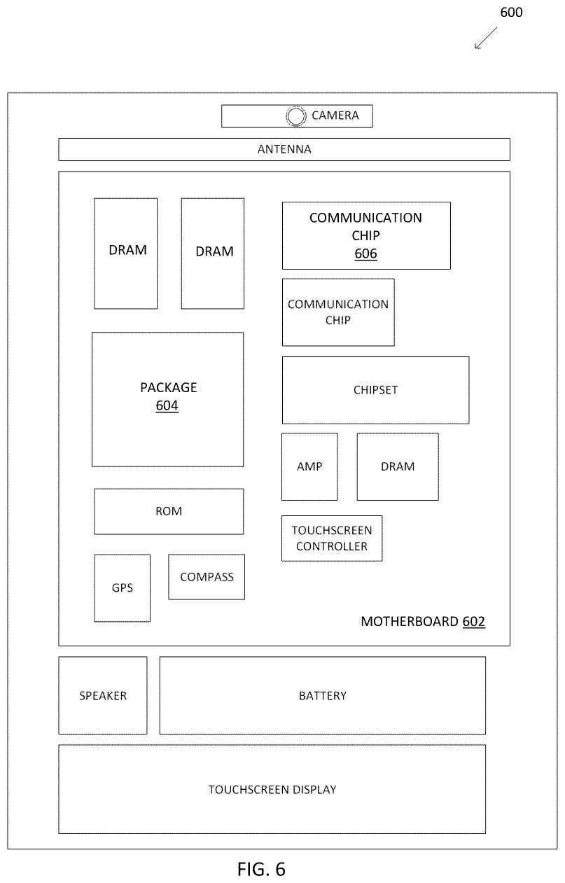

Aspects of the present disclosure may be implemented into a system using any suitable hardware and/or software. FIG. 6 schematically illustrates a computing device 600 that may include a device 100, 200, 300, 500 as described herein, in accordance with some aspects. The computing device 600 may house a board such as a motherboard 602. The motherboard 602 may include several components, including but not limited to a semiconductor package 604, according to the present disclosure, and at least one communication chip 606. The semiconductor package 604, which may include an interconnect structure integrated with a package substrate according to the present disclosure, may be physically and electrically coupled to the motherboard 602. In some implementations, the at least one communication chip 606 may also be physically and electrically coupled to the motherboard 602.

Depending on its applications, the computing device 600 may include other components that may or may not be physically and electrically coupled to the motherboard 602. These other components may include, but are not limited to, volatile memory (e.g., DRAM), non-volatile memory (e.g., ROM), flash memory, a graphics processor, a digital signal processor, a cryptoprocessor, a chipset, an antenna, a display, a touchscreen display, a touchscreen controller, a battery, an audio codec, a video codec, a power amplifier, a global positioning system (GPS) device, a compass, a Geiger counter, an accelerometer, a gyroscope, a speaker, a camera, and a mass storage device (such as hard disk drive, compact disk (CD), digital versatile disk (DVD), and so forth). In another aspect, the semiconductor package 604 of the computing device 600 may be assembled with a plurality of passive devices, as described herein.

The communication chip 606 may enable wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some aspects they might not. The communication chip 606 may implement any of several wireless standards or protocols, including but not limited to Institute for Electrical and Electronics Engineers (IEEE) standards including Wi-Fi (IEEE 502.11 family), IEEE 502.16 standards (e.g., IEEE 502.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 502.16 compatible BWA networks are generally referred to as WiMAX networks, an acronym that stands for Worldwide Interoperability for Microwave Access, which is a certification mark for products that pass conformity and interoperability tests for the IEEE 502.16 standards.

The communication chip 606 may also operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 606 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 606 may operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication chip 606 may operate in accordance with other wireless protocols in other aspects.

The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

In various implementations, the computing device 600 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In an aspect, the computing device 600 may be a mobile computing device. In further implementations, the computing device 600 may be any other electronic device that processes data.

### Examples

Example 1 may include a device, including a package substrate including at least one opening extending through the package substrate, and an interconnect structure including a first segment and a second segment. The first segment may extend under a bottom surface of the package substrate and may further extend beyond a footprint of the package substrate. The second segment may extend vertically from the first segment and may extend at least partially through the at least one opening of the package substrate.

Example 2 may include the subject matter of Example 1, wherein the interconnect structure may include at least one conductive plane isolated by a dielectric layer.

Example 3 may include the subject matter of Example 2, wherein the at least one conductive plane may include at least one of a reference plane coupled to a reference voltage, a power plane coupled to a power supply voltage, or a signal plane configured for signal transmission.

Example 4 may include the subject matter of Example 3, wherein the second segment may further include a decoupling capacitor coupled to the reference plane and the power plane.

Example 5 may include the subject matter of any one of Example 1 to 4, wherein the first segment may include a plurality of openings extending through the first segment.

Example 6 may include the subject matter of any one of Example 1 to 5, wherein the second segment may be coupled to the first segment.

Example 7 may include the subject matter of any one of Example 1 to 6, wherein a thickness of the first segment may be smaller than a thickness of the second segment.

Example 8 may include the subject matter of any one of Example 1 to 7, wherein the second segment may further extend beyond the at least one opening of the package substrate and beyond a top surface of the package substrate.

Example 9 may include the subject matter of any one of Example 1 to 8, wherein the interconnect structure may be attached to the package substrate through an epoxy polymer layer in the at least one opening of the package substrate.

Example 10 may include the subject matter of any one of Example 1 to 9, further including a passive component coupled to a top surface of the first segment outside the footprint of the package substrate.

Example 11 may include the subject matter of any one of Example 1 to 10, further including a die coupled to a top surface of the package substrate and a top surface of the second segment.

Example 12 may include the subject matter of Example 11, wherein the die may include a die substrate and a redistribution layer on the die substrate.

Example 13 may include the subject matter of Example 11 or 12, further including a plurality of chiplets coupled to the package substrate and the interconnect structure through the die.

Example 14 may include the subject matter of any one of Example 1 to 13, further including a printed circuit board coupled to the interconnect structure and the package substrate, wherein the first segment may extend between the package substrate and the printed circuit board.

Example 15 may include a method of forming a device, the method including forming an interconnect structure including a first segment and a second segment, wherein the second segment may extend vertically from the first segment; and coupling the interconnect structure to a package substrate having at least one opening extending through the package substrate, wherein the first segment may extend under a bottom surface of the package substrate and may further extend beyond a footprint of the package substrate, and wherein the second segment may extend at least partially through the at least one opening of the package substrate.

Example 16 may include the subject matter of Example 15, further including coupling a die to a top surface of the package substrate and a top surface of the second segment.

Example 17 may include the subject matter of Example 15 or 16, further including coupling the package substrate and the first segment of the interconnect structure to a printed circuit board.

Example 18 may include a computing device including a printed circuit board, a package substrate including at least one opening extending through the package substrate, an interconnect structure including a first segment and a second segment, a die coupled to a top surface of the package substrate and a top surface of the second segment, and a plurality of chiplets coupled to the package substrate and the interconnect structure through the die. The first segment may extend between the package substrate and the printed circuit board and may further extend beyond a footprint of the package substrate. The second segment may extend vertically from the first segment and may extend at least partially through the at least one opening of the package substrate.

Example 19 may include the subject matter of Example 18, wherein the interconnect structure may include at least one conductive plane isolated by a dielectric layer.

Example 20 may include the subject matter of Example 18 or 19, wherein the first segment may include a plurality of openings extending through the first segment, the plurality of openings being configured to accommodate solder bumps to couple the package substrate to the printed circuit board.

In a further example, any one or more of examples 1 to 20 may be combined.

These and other advantages and features of the aspects herein disclosed will be apparent through reference to the above description and the accompanying drawings. Furthermore, it is to be understood that the features of the various aspects described herein are not mutually exclusive and can exist in various combinations and permutations.

It will be understood that any property described herein for a specific device may also hold for any device described herein. It will also be understood that any property described herein for a specific method may hold for any of the methods described herein. Furthermore, it will be understood that for any device or method described herein, not necessarily all the components or operations described will be enclosed in the device or method, but only some (but not all) components or operations may be enclosed.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

While the present disclosure has been particularly shown and described with reference to specific aspects, it should be understood by those skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
a package substrate comprising at least one opening extending through the package substrate; and
an interconnect structure comprising a first segment and a second segment;
wherein the first segment extends under a bottom surface of the package substrate and further extends beyond a footprint of the package substrate, and
wherein the second segment extends vertically from the first segment and extends at least partially through the at least one opening of the package substrate.

2. The device of claim 1, wherein the interconnect structure comprises at least one conductive plane isolated by a dielectric layer.

3. The device of claim 2, wherein the at least one conductive plane comprises at least one of a reference plane coupled to a reference voltage, a power plane coupled to a power supply voltage, or a signal plane configured for signal transmission.

4. The device of claim 3, wherein the second segment further comprises a decoupling capacitor coupled to the reference plane and the power plane.

5. The device of claim 1, wherein the first segment comprises a plurality of openings extending through the first segment.

6. The device of claim 1, wherein the second segment is coupled to the first segment.

7. The device of claim 1, wherein a thickness of the first segment is smaller than a thickness of the second segment.

8. The device of claim 1, wherein the second segment further extends beyond the at least one opening of the package substrate and beyond a top surface of the package substrate.

9. The device of claim 1, wherein the interconnect structure is attached to the package substrate through an epoxy polymer layer in the at least one opening of the package substrate.

10. The device of claim 1, further comprising a passive component coupled to a top surface of the first segment outside the footprint of the package substrate.

11. The device of claim 1, further comprising a die coupled to a top surface of the package substrate and a top surface of the second segment.

12. The device of claim 11, wherein the die comprises a die substrate and a redistribution layer on the die substrate.

13. The device of claim 11, further comprising a plurality of chiplets coupled to the package substrate and the interconnect structure through the die.

14. The device of claim 1, further comprising a printed circuit board coupled to the interconnect structure and the package substrate, wherein the first segment extends between the package substrate and the printed circuit board.

15. A method comprising:
forming an interconnect structure comprising a first segment and a second segment, wherein the second segment extends vertically from the first segment; and
coupling the interconnect structure to a package substrate having at least one opening extending through the package substrate, wherein the first segment extends under a bottom surface of the package substrate and further extends beyond a footprint of the package substrate, and wherein the second segment extends at least partially through the at least one opening of the package substrate.

16. The method of claim 15, further comprising:
coupling a die to a top surface of the package substrate and a top surface of the second segment.

17. The method of claim 15, further comprising:
coupling the package substrate and the first segment of the interconnect structure to a printed circuit board.

18. A computing device comprising:
a printed circuit board;
a package substrate comprising at least one opening extending through the package substrate;
an interconnect structure comprising a first segment and a second segment, wherein the first segment extends between the package substrate and the printed circuit board and further extends beyond a footprint of the package substrate, and wherein the second segment extends vertically from the first segment and extends at least partially through the at least one opening of the package substrate;
a die coupled to a top surface of the package substrate and a top surface of the second segment; and
a plurality of chiplets coupled to the package substrate and the interconnect structure through the die.

19. The computing device of claim 18, wherein the interconnect structure comprises at least one conductive plane isolated by a dielectric layer.

20. The computing device of claim 18, wherein the first segment comprises a plurality of openings extending through the first segment, the plurality of openings being configured to accommodate solder bumps to couple the package substrate to the printed circuit board.
